(19) United States
(12) Patent Application Publication
(10) Pub. No.: US 2005/0156329 A1
(43) Pub. Date: Jul. 21, 2005

(54) Semiconductor device by embedded package

(76) Inventor: Charng Geng Sheen, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/743,777

(22) Filed: Dec. 24, 2003

(51) Int. Cl. H01L 21/336

(52) U.S. Cl. 257/780

(57) ABSTRACT

A semiconductor device by embedded package has a good mechanical property for assembly on the machine, especially for installation on a vehicle. The semiconductor device by embedded package can usually act as a power diode and has a nail head having a bonding end and a leading conductor, and a metal housing having a cavity inside. A bonding stage is formed on the metal housing within the cavity. A semiconductor chip is installed on the bonding stage with two sides connected to the nail head and the bonding stage respectively. The bonding stage has a fence at the edge thereof A well is formed around the bonding stage inside the cavity thereof. The metal housing has a inner side wall around the well and encloses the cavity.

### FIELD OF THE INVENTION

A semiconductor device by embedded package enjoys improved mechanical properties when assembled on an electrical circuit, especially when installed in a vehicle. The semiconductor device by embedded package is generally used as a power diode to rectify the electrical current.

### BACKGROUND OF THE INVENTION

The semiconductor device by embedded package used as a power diode is in great demand for in various kinds of vehicles, as is commonly known by persons in the related industrial field. A power diode has the benefit of rectifying electrical current for an electrical circuit. In particular, the power diode by embedded package has the ability to resist a bad environment when applied in vehicles. The electrical components of a vehicle are tested in a long procedure, after which qualified components are placed into practical application. The power diode by embedded package has very strict application requirements on which manufacturers thereof focus related research.

Reference is made to FIG. 1, which illustrates the conventional semiconductor device by embedded package as the power diode by the schematic sectional view. The semiconductor chip 22 is placed between the nail head 1 and the metal housing 2. The semiconductor chip 22 acts as an electrical current rectifier according to the requirements of circuit application. The metal housing 2 is filled with buffer material 12 to reduce unnecessary force toward the semiconductor chip 22, and also protects semiconductor chip 22 from moisture and dust. The inner side wall 24 surrounds the buffer material 12 to provide rigid support of the whole body. When the whole body of the power diode is inserted into the fitting plate 14, the housing will provide flexible force to the retention of the power diode.

But the conventional semiconductor device by embedded package as the power diode has many drawbacks. Firstly, the semiconductor chip 22 is very hard to fix in the center of the inner bottom of the metal housing 2. Also, the filled buffer material may be affected by thermal shock or mechanical impact to generate cracks. The cracks may allow moisture to enter the buffer material and damage the semiconductor chip 22. In addition, the buffer material is usually a resin, and resin is not a good insulator for a power diode for power rectifying.

Thus, from the above description, it is evident that the conventional semiconductor device by embedded package has drawbacks. These drawbacks should be improved for practical application.

### SUMMARY OF THE INVENTION

The main purpose of the present invention is to provide an improved structure of a semiconductor device serving as a power diode. The structure of new invention has a well inside to induce the stress during assembly to protect the semiconductor chip on the bonding stage. The structure of the present invention also provides a fence around the bonding stage to constrain the insulation glue. The bonding stage can further provide a good fixing place for the semiconductor chip. Thus the drawbacks of the conventional technique can be resolved. In short, the purpose of the present invention is to provide the semiconductor device for a power diode having good stress resistance during assembly, good insulation in a bonding area of the semiconductor chip, and a precise position for chip bonding.

The present invention comprises a nail head having a bonding end and a leading conductor and a metal housing having a cavity inside. A bonding stage is formed on the metal housing within the cavity. A semiconductor chip is installed on the bonding stage with two sides connected to the nail head and the bonding stage respectively. The bonding stage has a fence at the edge thereof. A well is formed around the bonding stage inside the cavity thereof. The metal housing has an inner side wall around the well and enclosing the cavity.

### BRIEF DESCRIPTION OF DRAWING

The various objects and advantages of the present invention will be more readily understood from the following detailed description when read in conjunction with the appended drawing, in which:

FIG. 1 shows a schematic, cross-sectional view of conventional technique;

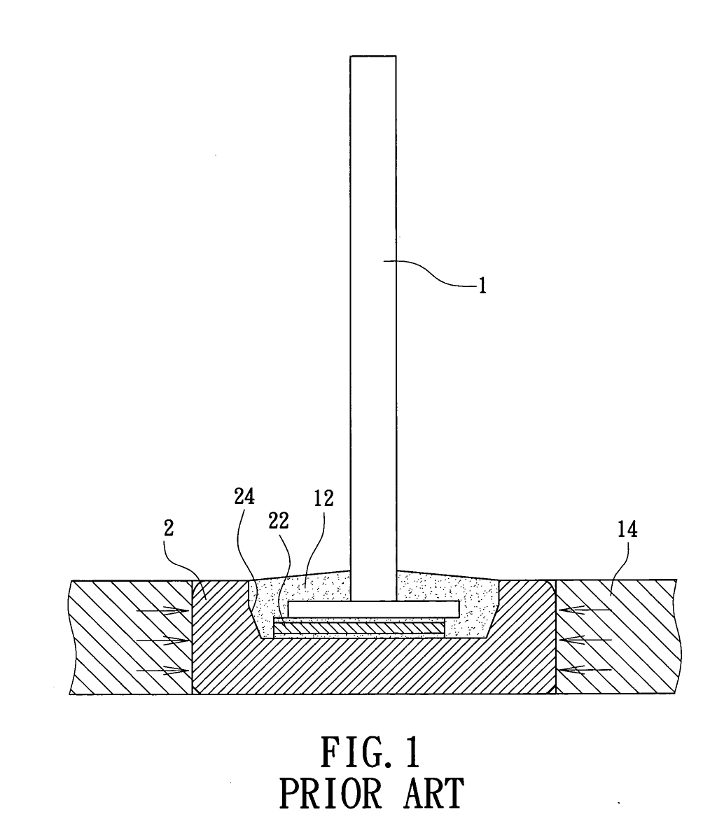

FIG. 2 shows a schematic, partial, cross-sectional view of first embodiment of the present invention; and

FIG. 3 shows a schematic, cross-sectional view of second embodiment of the present invention.

### DETAILED DESCRIPTION OF THE INVENTION

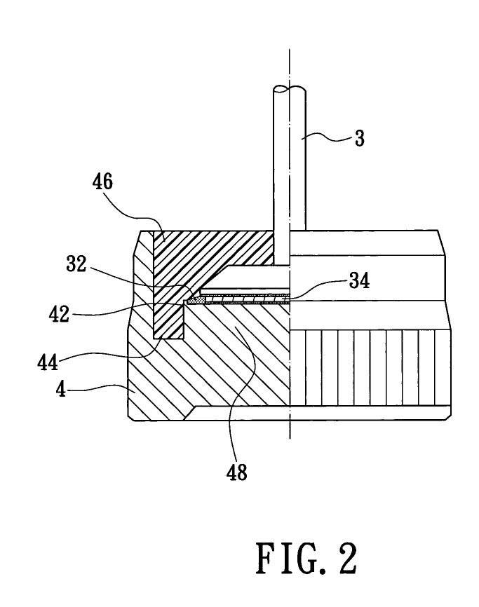

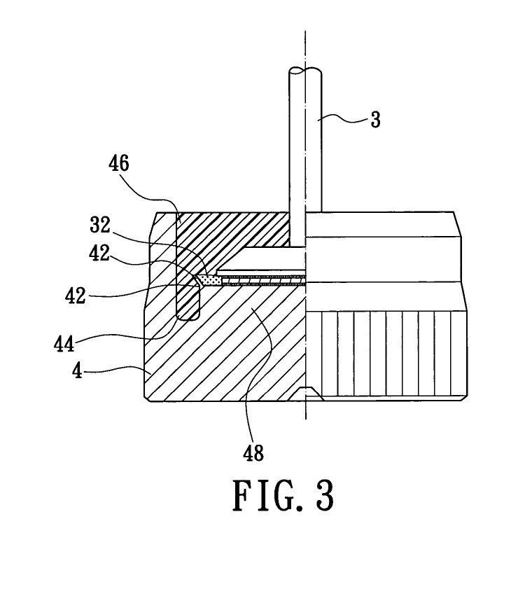

Reference is made to FIG. 2 and FIG. 3, with which the structure of the present invention is described. The diode structure of semiconductor device by embedded package of the present invention comprises many components. Firstly, the present invention comprises nail head 3 having a bonding end (bottom end) and a leading conductor (top end). The bonding end is connected to the semiconductor chip 34 for electrical power transfer. The semiconductor chip 34 is usually employed as the silicon wafer chip of a power diode for electrical current rectification. When the electrical current is transferred from the side of the leading conductor, the semiconductor chip has the ability to rectify the electrical current. This kind of application is usually used for electrical circuit protection to protect the electrical device from a power surge. Second, the present invention comprises a metal housing 4 having therein a cavity filled with buffer material 46. The buffer material 46 protects against outside dust and moisture. The metal housing 4 is also made of metal to provide stiffness and flexibility for assembly on a fitting plate. It should be noted that the bonding stage 48 is surrounded by the fence 42 and the well 44. The fence 42 constrains the insulation glue 32 to the bonding stage 48 and also constrains the semiconductor chip 34 to the bonding stage 48. The well 44 has induces assembly stress on the fitting plate so that the bonding stage 48 suffers very little deformation during assembly with the fitting plate. The buffer material can be a resin for suitable protection from moisture and the insulation glue can be an insulator for protection against electrical current leakage.

In sum, the present invention comprises a nail head 3 having a bonding end and a leading conductor and a metal housing 4 having a cavity inside. For transfer of electrical current transferring, both the nail head 3 and the metal housing 4 are made of conductive material. The cavity is filled with the buffer material 46 and is surrounded by the inner side wall at the upper portion of the metal housing 4. A bonding stage 48 is formed on the metal housing 4 within the cavity. A semiconductor chip 34 is installed on the bonding stage 48 with two sides connected to the nail head 3 and the bonding stage 48, respectively. The semiconductor chip 34 is the core component of the present invention and must be protected to maintain suitable conditions. The bonding stage 48 has a fence 42 at the edge thereof. A well 44 is formed around the bonding stage 48 inside the cavity thereof. The metal housing 4 has a inner side wall around the well 44 and enclosing the cavity.

Variations and the preferred embodiments are described in the following. The fence 42 slantingly extends from the side of bonding stage 48 to the side of inner side wall thereof. Reference is also made to FIG. 3 as a further embodiment for the shape of fence 42. The slantingly extending fence can provide good protection to the structure inside the cavity by acting as a barrier to guard the buffer material 46 and prevent moisture and dust from entering the cavity. The semiconductor chip 34 is surrounded by the insulation glue 32 and the insulation 32 glue constrained by the fence. The cavity can be filled with the buffer material.

Although the present invention has been described with reference to the preferred embodiment thereof, it will be understood that the invention is not limited to the details thereof. Various substitutions and modifications have suggested in the foregoing description, and others will occur to those of ordinary skill in the art. Therefore, all such substitutions and modifications are intended to be embraced within the scope of the invention as defined in the appended claims.

1. A semiconductor device by embedded package, comprising:
a nail head having a bonding end and a leading conductor; and
a metal housing having a cavity therein; wherein
a bonding stage is formed on the metal housing within the cavity;
a semiconductor chip is installed on the bonding stage with two sides connected to the nail head and the bonding stage, respectively;
the bonding stage has a fence at an edge thereof;
a well is formed around the bonding stage inside the cavity thereof; and
the metal housing has a inner side wall around the well and enclosing the cavity.

2. The semiconductor device by embedded package as claimed in claim 1, wherein the fence slantingly extends from side of bonding stage to side of an inner sidewall thereof.

3. The semiconductor device by embedded package as claimed in claim 1, wherein the semiconductor chip is surrounded by the insulation glue and the insulation glue is constrained by the fence.

4. The semiconductor device by embedded package as claimed in claim 1, wherein the cavity is filled with the buffer material.
